(19) United States
(12) Patent Application Publication
(10) Pub. No.: US 2026/0082989 A1
(43) Pub. Date: Mar. 19, 2026

(54) SEMICONDUCTOR APPARATUS

(71) Applicant: Mitsubishi Electric Corporation, Tokyo (JP)

(72) Inventor: Takayuki HISAKA, Tokyo (JP)

(73) Assignee: Mitsubishi Electric Corporation, Tokyo (JP)

(21) Appl. No.: 19/108,684

(22) PCT Filed: Dec. 27, 2022
(86) PCT No.: PCT/JP2022/048098

§ 371 Date: Mar. 4, 2025

(51) Int. Cl. H01L 23/057; H01L 23/00; H01L 23/31

(52) U.S. Cl. CPC H10W 76/157; H10W 74/114; H10W 90/752

(57) ABSTRACT

A semiconductor apparatus includes a substrate (12), a semiconductor chip (14) disposed on the substrate (12), a side wall (16) disposed on the substrate (12) and surrounding the semiconductor chip (14), and a lid (18) disposed on the side wall (16) and above the semiconductor chip (14) to form a hollow structure (22) together with the substrate (12), the semiconductor chip (14), and the side wall (16), the lid (18) including a penetrating portion (20) penetrating through the lid (18) to the interior of the hollow structure (22).

### FIELD

The present disclosure relates to a semiconductor apparatus.

### BACKGROUND

Some of semiconductor apparatuses use a hollow structure package having a hollow inside. A semiconductor chip is mounted inside the hollow structure package. In a case of using such a package, defects such as dew condensation inside the package may occur due to gas and/or moisture contained in gas in a hollow portion.

PTL 1 discloses a semiconductor apparatus in which a portion of the package where a lid is bonded is partially formed to be air permeable, in order to prevent dew condensation and the like inside the package.

Further, some of the semiconductor apparatuses use a mold package in which the inside of the package is filled with a resin. The resin is filled so as to cover the semiconductor chip. In such a package, airtightness is not maintained because the resin is used, and moisture and/or gas may intrude into the inside of the package from its periphery. In addition, an adhesive and the resin to be used also contain moisture and/or gas. As a result, the moisture and/or gas may reach a periphery of the semiconductor chip.

PTL 2 discloses a semiconductor apparatus that includes a through hole in a resin to discharge moisture and the like to an outside in order to prevent the moisture from reaching a periphery of the semiconductor chip.

### CITATION LIST

### Patent Literature

[PTL 2] JP H9-219471 A

### SUMMARY

### Technical Problem

The semiconductor apparatus disclosed in PTL 1 has an issue that an opening area of the air-permeable portion is small because the air-permeable portion is secured in a part of the portion where the lid is bonded. In the semiconductor apparatus disclosed in PTL 2, the through hole does not reach the semiconductor chip but reaches only an island of a lead terminal. Thus, an opening area of the air-permeable portion is also small. When the opening area of the air-permeable portion is small, discharge of moisture and/or gas is insufficient.

The present disclosure has been made to solve the above-described issues, and an object of the present disclosure is to provide a semiconductor apparatus that can sufficiently discharge moisture and/or gas.

### Solution to Problem

A first semiconductor apparatus according to the disclosure includes a substrate; a semiconductor chip disposed on the substrate; a side wall disposed on the substrate and surrounding the semiconductor chip; and a lid disposed on the side wall and above the semiconductor chip to form a hollow structure together with the substrate, the semiconductor chip, and the side wall, the lid including a penetrating portion penetrating through the lid up to the hollow structure.

A second semiconductor apparatus according to the disclosure includes a semiconductor substrate including a semiconductor device on a front surface; a side wall disposed on the front surface and surrounding the semiconductor device; and a lid disposed on the side wall and above the semiconductor device to form a hollow structure together with the front surface and the side wall, wherein the side wall includes a penetrating portion penetrating through the side wall up to the hollow structure.

A second semiconductor apparatus according to the disclosure includes a substrate; a semiconductor chip disposed on the substrate; and a sealing resin disposed on the substrate and covering the semiconductor chip, the sealing resin including a penetrating portion penetrating through the sealing resin between side surfaces opposite to each other to expose a front surface of the semiconductor chip.

### Advantageous Effects of Invention

According to the present disclosure, it is possible to provide the semiconductor apparatus that can sufficiently discharge moisture and/or gas.

### BRIEF DESCRIPTION OF DRAWINGS

FIG. 1 is a top view of a semiconductor apparatus according to Embodiment 1.

FIG. 2 is a cross-sectional view of the semiconductor apparatus according to Embodiment 1.

FIG. 3 is a cross-sectional view of the semiconductor apparatus according to Embodiment 1.

FIG. 4 illustrates the increasing amount of the drain leakage current after the moisture resistance test.

FIG. 5 is a top view of a semiconductor apparatus according to Embodiment 2.

FIG. 6 is a cross-sectional view of the semiconductor apparatus according to Embodiment 2.

FIG. 7 is a cross-sectional view of the semiconductor apparatus according to Embodiment 2.

FIG. 8 is a cross-sectional view of a semiconductor apparatus according to Embodiment 3.

### DESCRIPTION OF EMBODIMENTS

### Embodiment 1

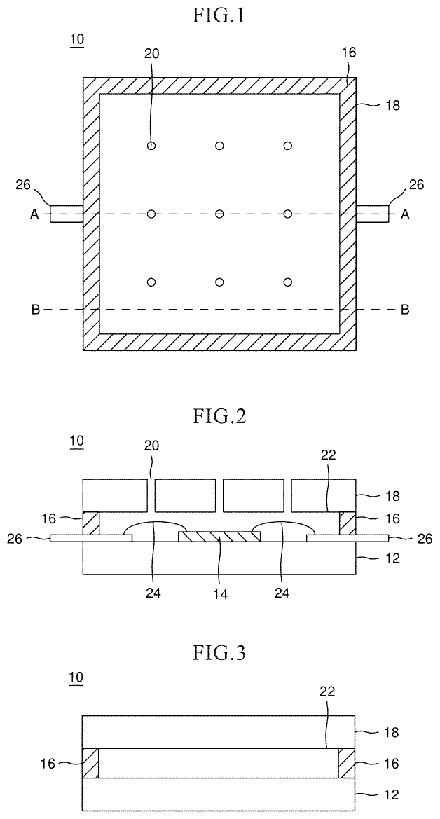

FIG. 1 to FIG. 3 illustrate a semiconductor apparatus 10 according to Embodiment 1. FIG. 1 is a top view, FIG. 2 is a cross-sectional view taken along line A-A in FIG. 1, and FIG. 3 is a cross-sectional view taken along line B-B in FIG. 1. The semiconductor apparatus 10 includes a substrate 12, a semiconductor chip 14, a side wall 16, a lid 18, wires 24, and lead terminals 26. The semiconductor apparatus 10 includes a hollow structure 22. In FIG. 1, the side wall 16 is illustrated in a transparent manner for description.

The substrate 12 is made of, for example, a resin.

The semiconductor chip 14 is disposed on the substrate 12. The semiconductor chip 14 is a chip manufactured using a semiconductor process, and may be an active component or a passive component. Alternatively, the semiconductor chip 14 may be MEMS (Micro Electro Mechanical Systems).

The side wall 16 is disposed on the substrate 12. The side wall 16 is disposed to surround the semiconductor chip 14. The side wall 16 is made of, for example, a resin.

The lid 18 is disposed on the side wall 16 and above the semiconductor chip 14. The hollow structure 22 is formed by the substrate 12, the semiconductor chip 14, the side wall 16, and the lid 18. The hollow structure 22 has a size of 8 mm×8 mm×1.5 mm. A front surface of the semiconductor chip 14 is exposed inside the hollow structure 22. The lid 18 is made of, for example, a metal.

The lid 18 includes penetrating portions 20 penetrating through the lid 18 up to the hollow structure 22. A plurality of the penetrating portions 20 are provided.

A shape of an opening of each of the penetrating portions 20 is a circle. A diameter of the circle of the opening of each of the penetrating portions 20 is desirably 0.5 mm or more and 1 mm or less. When the diameter is set to 0.5 mm or more, an effect of discharging moisture and/or gas can be enhanced. When the diameter is set to 1 mm or less, intrusion of a foreign substance having a size larger than the diameter can be prevented, and deformation of the semiconductor chip 14, the wires 24, and the like can be prevented. In addition, electric short circuit caused by intrusion of a conductive foreign substance can be prevented.

One end of each of the wires 24 is connected to an electrode of the semiconductor chip 14, and the other end of each of the wires 24 is connected to the corresponding lead terminal 26. The lead terminals 26 are drawn to an outside.

A moisture resistance test performed on the semiconductor apparatus mounted with a GaN HEMT (high electron mobility transistor) is described. A condition of the moisture resistance test was 130° C. and 85%, and voltages applied to a drain terminal and a gate terminal were respectively 30V and −5V. A test time was 300 hours. Four semiconductor apparatuses were prepared, the numbers of penetrating portions each having a diameter of 0.5 mm provided on the respective semiconductor apparatuses were 0, 3, 10 and 20, and an increasing amount of a drain leakage current after lapse of 300 hours was measured. Voltages applied to the drain terminal and the gate terminal during measurement of the drain leakage current were respectively 3V and −5V.

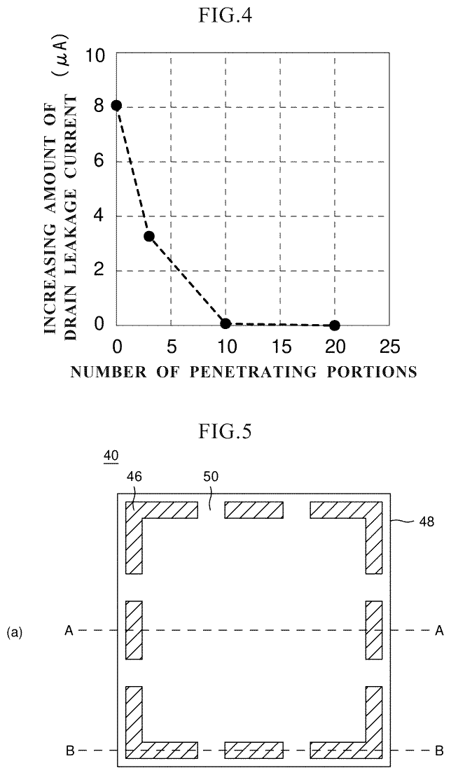

FIG. 4 illustrates the increasing amount of the drain leakage current after the moisture resistance test. It is found from the result that the increasing amount of the drain leakage current is reduced as the number of penetrating portions is increased. This is because a large amount of moisture and/or gas in the package can be discharged as the number of penetrating portions is increased. In addition, it is found that, when 10 or more penetrating portions are provided, the increasing amount of the drain leakage current is sufficiently small. When 10 penetrating portions are provided, a total area of the openings is 1.96 mm². Therefore, the area of the openings of the penetrating portions 20 is desirably 2 mm² or more.

As described above, according to the present embodiment, since the penetrating portions 20 are provided in the lid, it is possible to provide the semiconductor apparatus that can sufficiently discharge moisture and/or gas.

Note that the side wall 16 may be formed integrally with the substrate 12, or may be formed integrally with the lid 18. Further, the shape of the opening of each of the penetrating portions 20 may not be limited to the circle. The shape of the opening of each of the penetrating portions 20 may be, for example, a rectangle (including square) or a polygon. Alternatively, the shape of the opening of each of the penetrating portions 20 may be an ellipse.

### Embodiment 2

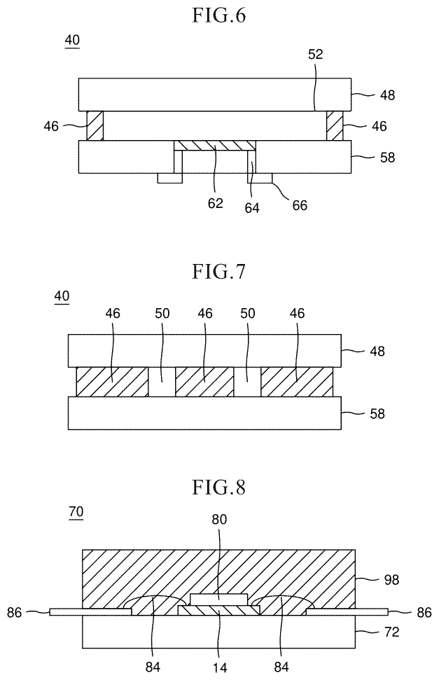

FIG. 5 to FIG. 7 illustrate a semiconductor apparatus 40 according to Embodiment 2. FIG. 5 is a top view, FIG. 6 is a cross-sectional view taken along line A-A in FIG. 5, and FIG. 7 is a cross-sectional view taken along line B-B in FIG. 5. The semiconductor apparatus 40 includes a semiconductor substrate 58, a side wall 46, and a lid 48. The semiconductor apparatus 40 includes a wafer level package (WLP) structure. In FIG. 5, the side wall 46 is illustrated in a transparent manner for description.

A semiconductor device 62 is provided on a front surface of the semiconductor substrate 58. The semiconductor device 62 may be an active component or a passive component. Alternatively, the semiconductor device 62 may be MEMS (Micro Electro Mechanical Systems). The semiconductor substrate 58 is obtained by, for example, stacking a GaN layer on a SiC substrate.

The side wall 46 is disposed on the front surface of the semiconductor substrate 58. The side wall 46 is disposed to surround the semiconductor device 62. The side wall 46 is made of, for example, a resin.

The lid 48 is disposed on the side wall 46 and above the semiconductor device 62. A hollow structure 52 is formed by the front surface of the semiconductor substrate 58, the side wall 46, and the lid 48. A front surface of the semiconductor device 62 is exposed inside the hollow structure 52. The lid 48 is made of, for example, a resin.

The side wall 46 includes penetrating portions 50 penetrating the side wall 46 up to the hollow structure 52. A plurality of the penetrating portions 50 are provided.

A shape of an opening of each of the penetrating portions 50 is a rectangle (including square) having a side perpendicular to the front surface of the semiconductor substrate 58. The rectangle extends from an uppermost part to a lowermost part of the side wall 46. A length of a side of the rectangle parallel to the front surface of the semiconductor substrate 58 is desirably 0.5 mm or more and 1 mm or less. When the length of the side is set to 0.5 mm or more, an effect of discharging moisture and/or gas can be enhanced. When the length of the side is set to 1 mm or less, intrusion of a foreign substance having a size larger than the length of the side can be prevented, and deformation of the semiconductor device 62 and the like can be prevented. In addition, electric short circuit caused by intrusion of a conductive foreign substance can be prevented. A total area of the openings of the penetrating portions 50 is desirably 2 mm² or more. When the total area of the openings of the penetrating portions 50 is set to 2 mm² or more, the effect of discharging moisture and/or gas can be enhanced.

The side wall 46 is formed using a patterning method. The side wall 46 is formed by patterning a resin. A mask pattern used for patterning is a pattern preventing the resin from being stacked on portions where the penetrating portions 50 are to be formed. When the penetrating portion 50 are formed by the patterning method in the above-described manner, an additional step is unnecessary.

The semiconductor device 62 is connected to a via hole 64, and the via hole 64 is connected to a rear-surface electrode 66 provided on a rear surface of the semiconductor substrate 58.

As described above, according to the present embodiment, since the penetrating portions 50 are provided in the side wall 46, it is possible to provide the semiconductor apparatus that can sufficiently discharge moisture and/or gas.

### Embodiment 3

FIG. 8 is a cross-sectional view of a semiconductor apparatus 70 according to Embodiment 3. The semiconductor apparatus 70 includes a substrate 72, the semiconductor chip 14, a sealing resin 98, wires 84, and lead terminals 86. The semiconductor apparatus 70 includes a mold package structure sealed with a resin.

The substrate 72 is made of, for example, a resin.

The semiconductor chip 14 is disposed on the substrate 72. The semiconductor chip 14 is a chip manufactured using a semiconductor process, and may be an active component or a passive component. Alternatively, the semiconductor chip 14 may be MEMS (Micro Electro Mechanical Systems).

The sealing resin 98 covering the semiconductor chip 14 is disposed on the substrate 72. The sealing resin 98 includes a penetrating portion 80 penetrating through the sealing resin 98 between side surfaces of the sealing resin 98 opposite to each other. The penetrating portion 80 penetrates through the sealing resin 98 from a front side to a back side on a paper surface in FIG. 8. The penetrating portion 80 exposes the front surface of the semiconductor chip 14.

A height of the penetrating portion 80 is desirably 0.5 mm or more and 1 mm or less. When the height is set to 0.5 mm or more, an effect of discharging moisture and/or gas can be enhanced. When the height is set to 1 mm or less, intrusion of a foreign substance having a size larger than the height can be prevented, and deformation of the semiconductor chip 14 and the like can be prevented. In addition, electric short circuit caused by intrusion of a conductive foreign substance can be prevented. A total area of openings of the penetrating portion 80 is desirably 2 mm² or more. When the total area of the openings of the penetrating portion 80 is set to 2 mm² or more, the effect of discharging moisture and/or gas can be enhanced.

To form the penetrating portion 80, an organic material film having chemical properties different from chemical properties of the sealing resin 98 is first formed on a portion to be the penetrating portion 80 by patterning. Thereafter, the sealing resin 98 is formed to cover the organic material film. Thereafter, the organic material film is dissolved and removed to form the penetrating portion 80. Alternatively, the lid-like sealing resin 98 including a recess may be bonded to the substrate 72 with an adhesive. In the method, the recess turns into the penetrating portion 80.

As described above, according to the present embodiment, since the penetrating portion 80 is provided in the lid, it is possible to provide the semiconductor apparatus that can sufficiently discharge moisture and/or gas.

### REFERENCE SIGNS LIST

10, 40, 70 semiconductor apparatus, 12, 72 substrate, 14 semiconductor chip, 16, 46, 76 side wall, 18, 48 lid, 20, 50, 80 penetrating portion, 22, 52 hollow structure, 58 semiconductor substrate, 62 semiconductor device, 98 sealing resin

1. A semiconductor apparatus comprising:
a substrate;
a semiconductor chip disposed on the substrate;
a side wall disposed on the substrate and surrounding the semiconductor chip; and
a lid disposed on the side wall and above the semiconductor chip to form a hollow structure together with the substrate, the semiconductor chip, and the side wall, the lid including a penetrating portion penetrating through the lid up to the hollow structure.

2. The semiconductor apparatus according to claim 1, wherein a shape of an opening of the penetrating portion is a circle.

3. The semiconductor apparatus according to claim 2, wherein a dimeter of the circle is 0.5 mm or more and 1 mm or less.

4. A semiconductor apparatus comprising:
a semiconductor substrate including a semiconductor device on a front surface;
a side wall disposed on the front surface and surrounding the semiconductor device; and
a lid disposed on the side wall and above the semiconductor device to form a hollow structure together with the front surface and the side wall, wherein
the side wall includes a penetrating portion penetrating through the side wall up to the hollow structure.

5. The semiconductor apparatus according to claim 4, wherein a shape of an opening of the penetrating portion is a rectangle having a side perpendicular to the front surface, and the rectangle extends from an uppermost part to a lowermost part of the side wall.

6. The semiconductor apparatus according to claim 5, wherein a length of a side of the rectangle parallel to the front surface is 0.5 mm or more and 1 mm or less.

7. A semiconductor apparatus comprising:
a substrate;
a semiconductor chip disposed on the substrate; and
a sealing resin disposed on the substrate and covering the semiconductor chip, the sealing resin including a penetrating portion penetrating through the sealing resin between side surfaces opposite to each other to expose a front surface of the semiconductor chip.

8. The semiconductor apparatus according to claim 7, wherein a height of the penetrating portion is 0.5 mm or more and 1 mm or less.

9. The semiconductor apparatus according to claim 1, wherein an area of an opening of the penetrating portion is 2 mm² or more.

10. The semiconductor apparatus according to claim 4, wherein an area of an opening of the penetrating portion is 2 mm² or more.

11. The semiconductor apparatus according to claim 7, wherein an area of an opening of the penetrating portion is 2 mm² or more.
